(19) United States
(12) Patent Application Publication
(10) Pub. No.: US 2021/0407353 A1
(43) Pub. Date: Dec. 30, 2021

(54) STRETCHABLE DISPLAY SUBSTRATE AND METHOD FOR MANUFACTURING THE SAME,DISPLAY DEVICE AND OPERATING METHOD

(71) Applicant: BOE TECHNOLOGY GROUP CO., LTD., Beijing (CN)

(72) Inventors: Hongwei TIAN, Beijing (CN); Yanan NIU, Beijing (CN); Dong LI, Beijing (CN); Ming LIU, Beijing (CN); Zheng LIU, Beijing (CN)

(21) Appl. No.: 17/280,826

(22) PCT Filed: May 29, 2020
(86) PCT No.: PCT/CN2020/093168

§ 371 Date: Mar. 26, 2021

(30) Foreign Application Priority Data
Jun. 24, 2019 (CN) 201910550178.6

(51) Int. Cl. G09G 3/00; G09G 3/3208; H01L 27/32; H01L 51/00; H01L 51/56

(52) U.S. Cl. CPC G09G 3/035; G09G 3/3208; H01L 27/3265; H01L 27/3276; H01L 2227/323; H01L 51/56; G09G 2320/0233; G09G 2320/0242; H01L 2251/5338; H01L 51/0097

(57) ABSTRACT

The present invention provides a stretchable display substrate, a method for manufacturing the same, a display device and an operating method thereof, and belongs to the field of display technologies. The stretchable display substrate includes a plurality of islands on a base substrate, and a plurality of connection bridges corresponding to each of the plurality of islands. The plurality of islands are distributed in array and separated from each other; the plurality of connection bridges corresponding to each island are configured to connect the island with islands adjacent to the island. An electrical detection structure is provided between each island and the plurality of connection bridges corresponding to the island, and the electrical detection structure is configured to have an electrical parameter changed when the stretchable display substrate is stretched.

### CROSS-REFERENCE TO RELATED APPLICATION

This application claims a priority to Chinese Patent Application No. 201910550178.6 filed on Jun. 24, 2019, the disclosure of which is incorporated in its entirety by reference herein.

### TECHNICAL FIELD

The present disclosure relates to the field of display technologies, in particular to a stretchable display substrate, a method for manufacturing the same, a display device and an operating method thereof.

### BACKGROUND

Organic light-emitting diode (Organic Light-Emitting Diode, OLED) has gradually become the mainstream in the display field due to its excellent performances such as low power consumption, high color saturation, wide viewing angle, small thickness, and flexibility, and is widely used in terminal products such as smart phones, tablet computers, and televisions. Among them, flexible OLED products are the most prominent, and become the mainstream of OLED displays as they can meet various special structures.

With the development of flexible display technology, OLED products have been updated gradually from bendable (Bendable) products, to foldable (Foldable) products, and further to elastic flexible (Stretchable) products. Stretchable OLED display substrates have received extensive attention from the market due to their wide application space. However, stretchable OLED display substrates also have many technical problems to be solved. For example, stretchable OLED display substrates may have problems such as color shift and brightness unevenness after being stretched, due to different stretch amounts in different stretched areas, which result in unsatisfactory display effects of the stretchable OLED display substrates.

### SUMMARY

To solve the above technical problems, embodiments of the present disclosure provide technical solutions as follows:

In one aspect, a stretchable display substrate is provided, including: a plurality of islands on a base substrate, and a plurality of connection bridges corresponding to each of the plurality of islands. The plurality of islands are distributed in array and separated from each other; the plurality of connection bridges corresponding to each island are configured to connect the island with islands adjacent to the island. An electrical detection structure is provided between each island and the plurality of connection bridges corresponding to the island, and the electrical detection structure is configured to have an electrical parameter changed when the stretchable display substrate is stretched.

Optionally, the electrical detection structure includes a capacitor, and a resistor.

Optionally, the capacitor includes a first electrode plate and a second electrode plate, the first electrode plate is located on a connection bridge of the plurality of the connection bridges, and the second electrode plate is located at a junction between the connection bridge and an island corresponding to the connection bridge.

Optionally, the first electrode plate is arranged in a same layer and made of a same material as a gate metal layer of the stretchable display substrate; and the second electrode plate is arranged in a same layer and made of a same material as a source-drain metal layer of the stretchable display substrate.

Optionally, both the first electrode plate and the second electrode plate are arranged in a same layer and made of a same material as a gate metal layer of the stretchable display substrate; or both the first electrode plate and the second electrode plate are arranged in a same layer and made of a same material as a source-drain metal layer of the stretchable display substrate.

Optionally, the first electrode plate and the second electrode plate are of S shape or comb shape.

An embodiment of the present disclosure also provides a stretchable display device, which includes the stretchable display substrate as described above, and further includes: a display drive circuit, connected to the electrical detection structure, and configured to: detect a change amount of the electrical parameter of the electrical detection structure, determine a stretch amount of an area where the electrical detection structure is located according to the change amount of the electrical parameter, and perform displaying compensation according to the stretch amount.

An embodiment of the present disclosure also provides an operating method of a stretchable display device, which is applied to the above-mentioned stretchable display device, and includes: detecting, by the display drive circuit, the change amount of the electrical parameter of the electrical detection structure; determining the stretch amount of the area where the electrical detection structure is located according to the change amount of the electrical parameter; and performing displaying compensation according to the stretch amount.

An embodiment of the present disclosure also provides a method for manufacturing a stretchable display substrate. The stretchable display substrate includes a plurality of islands on a base substrate, and a plurality of connection bridges corresponding to each of the plurality of islands; the plurality of islands are distributed in array and separated from each other; the plurality of connection bridges corresponding to each island are configured to connect the island with islands adjacent to the island. The manufacturing method includes: forming an electrical detection structure between each island and the plurality of connection bridges corresponding to the island, where an electrical parameter of the electrical detection structure changes when the stretchable display substrate is stretched.

Optionally, the electrical detection structure includes a capacitor and a resistor, and a step of forming the capacitor includes: forming a first electrode plate of the capacitor on a connection bridge of the plurality of connection bridges; forming a second electrode plate of the capacitor at a junction of the connection bridge and an island corresponding to the connection bridge.

Optionally, forming the electrical detection structure specifically includes: forming the first electrode plate and a gate metal layer of the stretchable display substrate through one patterning process; and forming the second electrode plate and a source-drain metal layer of the stretchable display substrate through one patterning process.

Optionally, forming the electrical detection structure specifically includes: forming the first electrode plate, the second electrode plate and a gate metal layer of the stretchable display substrate through one patterning process; or forming the first electrode plate, the second electrode plate and a source-drain metal layer of the stretchable display substrate through one patterning process.

### BRIEF DESCRIPTION OF THE DRAWINGS

FIG. 1 is a schematic structural diagram of a stretchable display substrate;

FIG. 2 is a schematic diagram of an electrical detection structure being a capacitor according to an embodiment of the present disclosure;

FIG. 3 is a schematic diagram of an electrode plate of a capacitor according to a specific embodiment of the present disclosure;

FIG. 4 is a schematic diagram of an electrode plate of a capacitor according to another specific embodiment of the present disclosure; and

FIG. 5 is a schematic diagram showing a position of an electrical detection structure according to an embodiment of the present disclosure.

### REFERENCE SIGNS

A: island

B: connection bridge

1: first electrode plate

2: dielectric layer

3: second electrode plate

4: base substrate

5: thin film transistor array layer

6: light-emitting unit

7: first inorganic film

8: organic film

9: second inorganic film.

### DETAILED DESCRIPTION

In order to make technical problems to be solved, technical solutions, and advantages of embodiments of the present disclosure clearer, a detailed description will be given below with reference to the accompanying drawings and specific embodiments.

OLED display devices have gradually become the main trend in the display field due to their excellent performances such as low power consumption, high color saturation, wide viewing angle, thin thickness, and flexibility, and widely used in terminal products such as smart phones, tablet computers, and televisions. Flexible OLED products are the most prominent among them, and become the mainstream of OLED displays as they can meet various special structures.

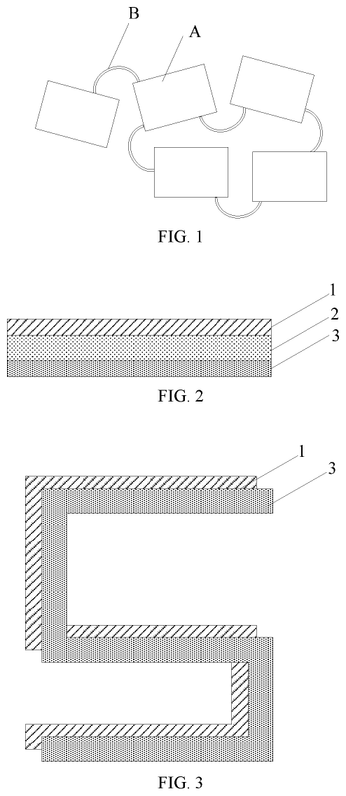

With the development of flexible display technology, OLED products have been gradually transitioned from bendable products and foldable products to elastic flexible products. The stretchable OLED display substrates have been widely concerned by the market due to their wide application space. As shown in FIG. 1, the stretchable display substrate includes a plurality of islands A that are distributed in an array on a base substrate and separated from each other, and a plurality of connection bridges B for connecting the plurality of islands. The connection bridge B can be deformed, so that the display substrate can be stretched. After the display substrate is stretched, due to different stretch amounts in different stretched areas, problems such as color shift and brightness unevenness may occur, resulting in undesirable display effects of the stretchable OLED display substrate.

In view of the above-mentioned problems, embodiments of the present disclosure provide a stretchable display substrate, a method for manufacturing the same, a display device and an operating method thereof, which can improve the display effects of the stretchable display substrate.

An embodiment of the present disclosure provides a stretchable display substrate, including: a plurality of islands on a base substrate, and a plurality of connection bridges corresponding to each of the plurality of islands. The plurality of islands are distributed in array and separated from each other; the plurality of connection bridges corresponding to each island are configured to connect the island with islands adjacent to the island. An electrical detection structure is provided between each island and each of the plurality of connection bridges corresponding to the island, and when the stretchable display substrate is stretched, an electrical parameter of the electrical detection structure changes.

In the embodiment, electrical detection structures are provided at the junction between an island and its adjacent connection bridges. When the stretchable display substrate is stretched, electrical parameters of the electrical detection structures change. In such way, a change amount of the electrical parameter may be detected, and a stretch amount of an area where the electrical detection structure is located is determined according to the change amount of the electrical parameter of the electrical detection structure, which provides a certain reference for compensation of brightness and color shift after stretching. Thus, the display can be compensated through a corresponding algorithm based on the measured stretch amount, so as to avoid or reduce the color shift and uneven brightness of the stretchable display substrate after stretching, and improve the display effect of the stretchable display substrate.

When stretched, the stretchable display substrate has different stretch amounts in different stretched areas, therefore, a relative position between the island and the connection bridge may change to a certain extent, especially a junction between the island and the connection bridge. Therefore, by arranging electrical detection structures at the junction of an island and connection bridges adjacent to the island, a relative position change between the island and the connection bridge may be monitored, the actual stretch amount may be fed back, and then the display may be compensated through a corresponding algorithm based on the stretch amount, so as to avoid or reduce the color shift and uneven brightness of the stretchable display substrate after stretching, and improve the display effect of the stretchable display substrate.

The electrical detection structure may be a capacitor or a resistor. When the stretchable display substrate is stretched, a main deformation area is the connection bridges. The electrical detection structure is located at the junction of the island and the connection bridge, and part of the electrical detection structure is located on the connection bridge. Therefore, the electrical parameter of the electrical detection structure may change after the stretching, a stretch amount of an area where the electrical detection structure is located is determined according to the change amount of the electrical parameter of the electrical detection structure, and then the display is compensated through a corresponding algorithm based on the stretch amount, so as to avoid or reduce the color shift and uneven brightness of the stretchable display substrate after stretching, thereby improving the experience of viewers.

In a case that the electrical detection structure is a resistor, the resistor is located at the junction of the island and the connection bridge. In such way, after the stretchable display substrate is stretched, the connection bridge is deformed, resulting in a change in a length and/or thickness of the resistor, which in turn leads to a change in a resistance of the resistor, and the corresponding stretch amount may be determined by detecting the change amount of the resistance.

In a specific embodiment, the capacitor includes a first electrode plate and a second electrode plate, the first electrode plate may be located on a connection bridge, and the second electrode plate may be located at the junction of the connection bridge and one of islands corresponding to the connection bridge. In this way, after the stretchable display substrate is stretched, the connection bridge is deformed, which in turn causes a change in a relative position between the first electrode plate and the second electrode plate, and further causes a change in a distance between the first electrode plate and the second electrode plate, and this change may cause the capacitance of the capacitor to change accordingly. By detecting a change amount of the capacitance, the corresponding stretch amount may be determined.

In a specific embodiment, the first electrode plate and a gate metal layer of the stretchable display substrate may be arranged in a same layer and made of a same material, so that the first electrode plate and the gate metal layer of the stretchable display substrate can be formed at the same time through a single patterning process, without any additional patterning process to specifically manufacture the first electrode plate, which can reduce the number of patterning processes for manufacturing the stretchable display substrate, save time for manufacturing the stretchable display substrate, and reduce the production cost of the stretchable display substrate. The second electrode plate and a source-drain metal layer of the stretchable display substrate may be arranged in a same layer and made of a same material, so that the second electrode plate and the source-drain metal layer of the stretchable display substrate can be formed at the same time through a single patterning process, without any additional patterning process to specifically manufacture the second electrode plate, which can reduce the number of patterning processes for manufacturing the stretchable display substrate, save time for manufacturing the stretchable display substrate, and reduce the production cost of the stretchable display substrate.

In another specific embodiment, the first electrode plate and the second electrode plate are arranged in a same layer, both of which may be arranged in a same layer and made of a same material as a gate metal layer of the stretchable display substrate. In such a manner, the first electrode plate, the second electrode plate and the gate metal layer of the stretchable display substrate may be formed at the same time through one patterning process, and there is no need to specially fabricate the first electrode plate and the second electrode plate through any additional patterning process, which can reduce the number of patterning processes for manufacturing the stretchable display substrate, save time for manufacturing the stretchable display substrate, and reduce the production cost of the stretchable display substrate.

In another specific embodiment, both the first electrode plate and the second electrode plate may be arranged in a same layer and made of a same material as a source-drain metal layer of the stretchable display substrate. In such a manner, the first electrode plate, the second electrode plate and the source-drain metal layer of the stretchable display substrate may be formed at the same time through one patterning process, and there is no need to specially fabricate the first electrode plate and the second electrode plate through an additional patterning process, which can reduce the number of patterning processes for manufacturing the stretchable display substrate, save time for manufacturing the stretchable display substrate, and reduce the production cost of the stretchable display substrate.

In a specific example, as shown in FIG. 2, in a case that the electrical detection structure is a capacitor, the capacitor includes a first electrode plate 1, a second electrode plate 3 and a dielectric layer 2. In order to make a maximum possible detection of the stretch amount through the capacitor, a capacitance value of the capacitor should be as large as possible. The capacitance value of the capacitor is determined by an overlap area of the first electrode plate 1 and the second electrode plate 3, and a distance between the first electrode plate 1 and the second electrode plate 3. In order to increase the capacitance value of the capacitor, optionally, as shown in FIG. 3, the first electrode plate 1 and the second electrode plate 3 are S-shaped. Optionally, as shown in FIG. 4, the first electrode plate 1 and the second electrode plate 3 are comb-shaped, which can increase the overlapping area between the first electrode plate 1 and the second electrode plate 3, thereby increasing the capacitance value of the capacitor.

An embodiment of the present disclosure also provides a stretchable display device, which includes the stretchable display substrate as described above, and further includes: a display drive circuit, connected to the electrical detection structure, and configured to: detect a change amount of the electrical parameter of the electrical detection structure, determine a stretch amount of an area where the electrical detection structure is located according to the change amount of the electrical parameter, and perform displaying compensation according to the stretch amount.

In the embodiment, an electrical detection structure is provided at the junction of an island and each of its adjacent connection bridges. When the stretchable display substrate is stretched, the electrical parameter of the electrical detection structure changes. In such way, a change amount of the electrical parameter of the electrical detection structure may be detected, and a stretch amount of an area where the electrical detection structure is located may be determined according to the change amount of the electrical parameter of the electrical detection structure, which provides a certain reference for compensation of brightness and color shift after stretching. Thus, the display can be compensated through a corresponding algorithm based on the measured stretch amount, so as to avoid or reduce the color shift and uneven brightness of the stretchable display substrate after stretching, and improve the display effect of the stretchable display substrate.

Specifically, a brightness of a corresponding area (that is, an area where the electrical detection structure is located) may be compensated according to the change in the stretch amount. In a case that pixels of different colors are not on a same island, the chromaticity of a corresponding area may also be adjusted according to the change in the stretch amount. When compensation is performed, the brightness of pixels in the corresponding area may be increased, or the brightness of pixels in other areas may be lowered, so that the overall brightness of the stretchable display substrate has better uniformity.

The display device includes, but not limited to: a radio frequency unit, a network module, an audio output unit, an input unit, a sensor, a display unit, a user input unit, an interface unit, a memory, a processor, a power supply and other components. Those skilled in the art can understand that the structure of the above display device does not constitute a limitation onto the display device, and the display device may include more or less of the above components, or combine some components, or have different component arrangements. In the embodiments of the present disclosure, the display device includes, but not limited to, a display, a mobile phone, a tablet computer, a television, a wearable electronic device, a navigation display device, and the like.

An embodiment of the present disclosure also provides an operating method of a stretchable display device, which is applied to the above-mentioned stretchable display device, and includes: detecting, by the display drive circuit, the change amount of the electrical parameter of the electrical detection structure; determining the stretch amount of the area where the electrical detection structure is located according to the change amount of the electrical parameter; and performing displaying compensation according to the stretch amount.

In the embodiment, an electrical detection structure is provided at the junction of an island and its adjacent connection bridge. When the stretchable display substrate is stretched, the electrical parameter of the electrical detection structure is changed. In such way, a change amount of the electrical parameter may be detected, and a stretch amount of an area where the electrical detection structure is located is determined according to the change amount of the electrical parameter of the electrical detection structure, which provides a certain reference for compensation of brightness and color shift after stretching. Thus, the displaying can be compensated through a corresponding algorithm based on the measured stretch amount, so as to avoid or reduce the color shift and uneven brightness of the stretchable display substrate after stretching, and improve the display effect of the stretchable display substrate. Specifically, a brightness of a corresponding area (that is, an area where the electrical detection structure is located) may be compensated according to the change in the stretch amount. In a case that pixels of different colors are not on a same island, the chromaticity of a corresponding area may also be adjusted according to the change in the stretch amount. When compensation is performed, the brightness of pixels in the corresponding area may be increased, or the brightness of pixels in other areas may be lowered, so that the overall brightness of the stretchable display substrate has better uniformity.

In a specific embodiment, a change amount of the electrical parameter of the electrical detection structure may be detected, and an amount of stretching in an area where the electrical detection structure is located is determined according to the change amount of the electrical parameter of the electrical detection structure. The amount of stretching is converted into an electrical signal and then amplified and transmitted to a display drive circuit of the display device. The display drive circuit adjusts a display drive signal inputted to the stretchable display substrate according to the amount of stretching, thereby realizing the adjustment of the display effects of the stretchable display substrate.

An embodiment of the present disclosure also provides a method for manufacturing a stretchable display substrate. The stretchable display substrate comprises: a plurality of islands on a base substrate, and a plurality of connection bridges corresponding to each of the plurality of islands; the plurality of islands are distributed in array and separated from each other; the plurality of connection bridges corresponding to each island are configured to connect the island with islands adjacent to the island. The manufacturing method includes: forming an electrical detection structure between each island and each of the plurality of connection bridges corresponding to the island, where an electrical parameter of the electrical detection structure changes when the stretchable display substrate is stretched.

In the embodiment, an electrical detection structure is provided at the junction of an island and its adjacent connection bridge. When the stretchable display substrate is stretched, the electrical parameter of the electrical detection structure changes. In this way, a change amount of the electrical parameter may be detected, and a stretch amount of an area where the electrical detection structure is located is determined according to the change amount of the electrical parameter of the electrical detection structure, which provides a certain reference for compensation of brightness and color shift after stretching. Thus, the display can be compensated through a corresponding algorithm based on the measured stretch amount, so as to avoid or reduce the color shift and uneven brightness of the stretchable display substrate after stretching, and improve the display effect of the stretchable display substrate.

When stretched, the stretchable display substrate has different stretch amounts in different stretched areas, therefore, a relative position junction the island and the connection bridge may change to a certain extent, especially a junction between the island and the connection bridge. Therefore, by arranging an electrical detection structure at the junction of an island and a connection bridge adjacent to the island, a change of the relative position between the island and the connection bridge may be monitored, the actual stretch amount may be fed back, and then the display may be compensated through a corresponding algorithm based on the stretch amount, so as to avoid or reduce the color shift and uneven brightness of the stretchable display substrate after stretching, and improve the display effect of the stretchable display substrate.

The electrical detection structure may be a capacitor or a resistor. When the stretchable display substrate is stretched, a main deformation area is the connection bridge. Since the electrical detection structure is located at the junction of the island and the connection bridge, and a part of the electrical detection structure is located on the connection bridge, the electrical parameter of the electrical detection structure may change after the stretching, a stretch amount of an area where the electrical detection structure is located is determined according to the change amount of the electrical parameter of the electrical detection structure, and then the display is compensated through a corresponding algorithm based on the stretch amount, so as to avoid or reduce the color shift and uneven brightness of the stretchable display substrate after stretching, thereby improving the experience of viewers.

In a case that the electrical detection structure is a resistor, the resistor is located at the junction of the island and the connection bridge. In such way, after the stretchable display substrate is stretched, the connection bridge is deformed, resulting in a change in a length and/or thickness of the resistor, which in turn leads to a change in a resistance of the resistor, and the corresponding stretch amount may be determined by detecting the change amount of the resistance.

In a specific embodiment, the electrical detection structure is a capacitor, the capacitor includes a first electrode plate and a second electrode plate, and forming the electrical detection structure includes: forming the first electrode plate of the capacitor on a connection bridge; and forming the second electrode plate of the capacitor at the junction of the connection bridge and an island corresponding to the connection bridge. In this way, after the stretchable display substrate is stretched, the connection bridge is deformed, which in turn causes a change in a relative position of the first electrode plate and the second electrode plate, and further causes a change in a distance between the first electrode plate and the second electrode plate, and this change may cause the capacitance of the capacitor to change accordingly. By detecting a change amount of the capacitance, the corresponding stretch amount may be determined.

In a specific embodiment, the first electrode plate and a gate metal layer of the stretchable display substrate may be arranged in a same layer and made of a same material, so that the first electrode plate and the gate metal layer of the stretchable display substrate may be formed at the same time through one patterning process, without any additional patterning process to specifically fabricate the first electrode plate, which can reduce the number of patterning processes for manufacturing the stretchable display substrate, save time for manufacturing the stretchable display substrate, and reduce the production cost of the stretchable display substrate. The second electrode plate and a source-drain metal layer of the stretchable display substrate may be arranged in a same layer and made of a same material, so that the second electrode plate and the source-drain metal layer of the stretchable display substrate may be formed at the same time through one patterning process, without any additional patterning process to specifically form the second electrode plate, which can reduce the number of patterning processes for manufacturing the stretchable display substrate, save time for manufacturing the stretchable display substrate, and reduce the production cost of the stretchable display substrate. Forming the electrical detection structure specifically includes: forming the first electrode plate and the gate metal layer of the stretchable display substrate through a same patterning process; and forming the second electrode plate and the source-drain metal layer of the stretchable display substrate through a same patterning process.

In another specific embodiment, the first electrode plate and the second electrode plate are arranged in a same layer, both of which may be arranged in a same layer and made of a same material as a gate metal layer of the stretchable display substrate. In such a manner, the first electrode plate, the second electrode plate and the gate metal layer of the stretchable display substrate may be formed at the same time through one patterning process, and there is no need to specially fabricate the first electrode plate and the second electrode plate through an additional patterning process, which can reduce the number of patterning processes for manufacturing the stretchable display substrate, save time for manufacturing the stretchable display substrate, and reduce the production cost of the stretchable display substrate. Forming the electrical detection structure specifically includes: forming the first electrode plate, the second electrode plate, and the gate metal layer of the stretchable display substrate through a same patterning process.

In another specific embodiment, both the first electrode plate and the second electrode plate may be arranged in a same layer and made of a same material as a source-drain metal layer of the stretchable display substrate. In such a manner, the first electrode plate, the second electrode plate and the source-drain metal layer of the stretchable display substrate may be formed at the same time through one patterning process, and there is no need to specially fabricate the first electrode plate and the second electrode plate through an additional patterning process, which can reduce the number of patterning processes for manufacturing the stretchable display substrate, save time for manufacturing the stretchable display substrate, and reduce the production cost of the stretchable display substrate. Forming the electrical detection structure specifically includes: forming the first electrode plate, the second electrode plate, and the source-drain metal layer of the stretchable display substrate through a same patterning process.

Taking the electrical detection structure being a capacitor as an example, the stretchable display substrate and the method for manufacturing the same of the present disclosure will be further introduced with reference to the accompanying drawings and a specific embodiment. The method for manufacturing the stretchable display substrate according to the embodiment includes the following steps.

Step 1, providing a base substrate 4, and forming a thin film transistor array layer 5 on the base substrate 4.

The base substrate 4 is a flexible substrate, and specifically, may be made of a polyimide film;

The thin film transistor array layer 5 includes a buffer layer, a gate metal layer pattern, a source-drain metal layer pattern, a gate insulation layer, an active layer, an interlayer insulation layer, a planarization layer and other film layers, which are used to form a thin film transistor and signal lines, etc.

The gate metal layer pattern includes a gate line, a gate electrode of the thin film transistor, and also includes the first electrode plate 1. The source-drain metal layer pattern includes a data line, a source electrode and a drain electrode of the thin film transistor, and also includes the second electrode plate 3. The insulating film layer between the gate metal layer pattern and the source-drain metal layer pattern forms the dielectric layer between the first electrode plate 1 and the second electrode plate 3, and the first electrode plate 1, the dielectric layer and the second electrode plate 3 form a capacitor.

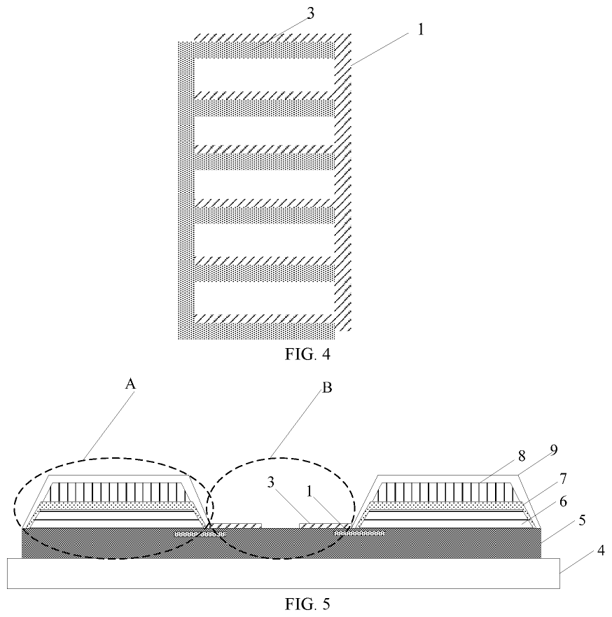

As shown in FIG. 5, the first electrode plate 1 is located at the junction of an island and a connection bridge, and the second electrode plate 3 is located on the connection bridge.

Step 2, forming a light-emitting unit 6 and an encapsulation layer covering the light-emitting unit 6.

As shown in FIG. 5, the light-emitting unit 6 and the encapsulation layer are only located in an area where the island of the stretchable display substrate is located. The light-emitting unit 6 includes a cathode, an anode, and a light-emitting layer located between the cathode and the anode. The encapsulation layer includes a first inorganic thin film 7, organic thin film 8, and second inorganic thin film 9, which are laminated.

Of course, the stretchable display substrate is not limited to include the above-mentioned film layers, but also includes other film layers, such as a pixel defining layer, a spacer, etc., which will not be described herein.

The stretchable display substrate as shown in FIG. 5 may be obtained through the above steps. As shown in FIG. 5, the stretchable display substrate includes islands and connection bridges, and adjacent islands are connected by a connection bridge. A capacitor is provided at the junction of the island and the connection bridge. The capacitor includes a first electrode plate 1 and a second electrode plate 3. The first electrode plate 1 is made of a gate metal layer of the stretchable display substrate, and the second electrode plate 3 is made of a source-drain metal layer of the stretchable display substrate. When the stretchable display substrate is stretched, the connection bridge is deformed, and a relative position between the island and the connection bridge changes, which results in a change of the relative position between the first electrode plate 1 and the second electrode plate 3, and further results in a change of a capacitance of the capacitor formed by the first electrode plate 1 and the second electrode plate 3. Thus, a corresponding stretch amount may be determined by detecting the change amount of the capacitance.

The display device includes a display drive circuit, which is electrically connected to each capacitor. According to the detected change amount of the capacitance, the stretch amount of the area where the capacitor is located may be determined. The display drive circuit adjusts a display driving signal that is inputted into the stretchable display substrate, according to the stretch amount, so as to realize the adjustment of the display effects of the stretchable display substrate.

It is noted, the embodiments provided in the specification are described in a progressive manner and the description of each embodiment focuses on its difference from other embodiments, thus the same or similar part among various embodiments may be referred to each other. In particular, for method embodiments, since they are essentially similar to the product embodiments, description of the method embodiments is relatively simple. For a relevant description, reference may be made to the description of the product embodiments.

It is understood by persons skilled in the art that, unless defined otherwise, all technical and scientific terms used herein have the same meaning as commonly understood by one of ordinary skill in the art to which this application belongs. Terms such as “first”, “second” and the like in this disclosure are adopted not to describe a specific sequence, quantity or importance, but to distinguish different components. Term such as “include”, “have” or any variant thereof refers to that an element or object preceding the term covers elements or objects and equivalents thereof listed behind the term, and does not preclude other elements or objects. The term “connection”, “couple”, or the like is not intended to be limited to a physical or mechanical connection. Rather, an electrical connection, whether direct or indirect, is encompassed. The terms such as “upper”, “lower”, “left”, “right” and the like are merely used to denote a relative positional relationship. When the absolute position of a described object changes, the relative positional relationship may change accordingly.

It will be understood that when an element, such as a layer, a film, an area or a substrate, is referred to as being “above” or “below” another element, it can be “directly above” or “directly below” the other element or intervening elements may also be present.

In the description of the foregoing implementations, specific characteristics, structures, materials or features may be combined in appropriate manner in any one or more embodiments or examples.

The aforementioned are merely specific implementations of the present disclosure, but the scope of the disclosure is by no means limited thereto. Any modifications or replacements that would easily occurred to those skilled in the art, without departing from the technical scope disclosed in the disclosure, should be encompassed in the scope of the present disclosure. Therefore, the scope of the present disclosure shall be determined by the scope of the claims.

1. A stretchable display substrate, comprising: a plurality of islands on a base substrate, and a plurality of connection bridges corresponding to each of the plurality of islands;
wherein the plurality of islands are distributed in array and separated from each other;
the plurality of connection bridges corresponding to each island are configured to connect the island with islands adjacent to the island; and
wherein, an electrical detection structure is provided between each island and the plurality of connection bridges corresponding to the island, and the electrical detection structure is configured to have an electrical parameter changed when the stretchable display substrate is stretched.

2. The stretchable display substrate according to claim 1, wherein the electrical detection structure comprises a capacitor, and/or a resistor.

3. The stretchable display substrate according to claim 2, wherein the capacitor comprises a first electrode plate and a second electrode plate, the first electrode plate is located on a connection bridge of the plurality of connection bridges, and the second electrode plate is located at a junction between the connection bridge and an island corresponding to the connection bridge.

4. The stretchable display substrate according to claim 3, wherein the first electrode plate is arranged in a same layer and made of a same material as a gate metal layer of the stretchable display substrate; and
the second electrode plate is arranged in a same layer and made of a same material as a source-drain metal layer of the stretchable display substrate.

5. The stretchable display substrate according to claim 3, wherein both the first electrode plate and the second electrode plate are arranged in a same layer and made of a same material as a gate metal layer of the stretchable display substrate; or
both the first electrode plate and the second electrode plate are arranged in a same layer and made of a same material as a source-drain metal layer of the stretchable display substrate.

6. The stretchable display substrate according to claim 3, wherein the first electrode plate and the second electrode plate are of S shape or comb shape.

7. A stretchable display device, comprising the stretchable display substrate according to claim 1, and further comprising:
a display drive circuit, connected to the electrical detection structure, and configured to: detect a change amount of the electrical parameter of the electrical detection structure, determine a stretch amount of an area where the electrical detection structure is located according to the change amount of the electrical parameter, and perform displaying compensation according to the stretch amount.

8. An operating method of a stretchable display device, applied to the stretchable display device according to claim 7, comprising:
detecting, by the display drive circuit, the change amount of the electrical parameter of the electrical detection structure; determining the stretch amount of the area where the electrical detection structure is located according to the change amount of the electrical parameter; and performing displaying compensation according to the stretch amount.

9. A method for manufacturing a stretchable display substrate, wherein the stretchable display substrate comprises: a plurality of islands on a base substrate, and a plurality of connection bridges corresponding to each of the plurality of islands; the plurality of islands are distributed in array and separated from each other; the plurality of connection bridges corresponding to each island are configured to connect the island with islands adjacent to the island, wherein the manufacturing method comprises:
forming an electrical detection structure between each island and the plurality of connection bridges corresponding to the island, wherein an electrical parameter of the electrical detection structure changes when the stretchable display substrate is stretched.

10. The method for manufacturing a stretchable display substrate according to claim 9, wherein the electrical detection structure comprises a capacitor and/or a resistor, and a step of forming the capacitor comprises:
forming a first electrode plate of the capacitor on a connection bridge of the plurality of connection bridges;
forming a second electrode plate of the capacitor at a junction of the connection bridge and an island corresponding to the connection bridge.

11. The method for manufacturing a stretchable display substrate according to claim 10, wherein forming the electrical detection structure specifically comprises:
forming the first electrode plate and a gate metal layer of the stretchable display substrate through one patterning process; and
forming the second electrode plate and a source-drain metal layer of the stretchable display substrate through one patterning process.

12. The method for manufacturing a stretchable display substrate according to claim 10, wherein forming the electrical detection structure specifically comprises:
forming the first electrode plate, the second electrode plate and a gate metal layer of the stretchable display substrate through one patterning process; or
forming the first electrode plate, the second electrode plate and a source-drain metal layer of the stretchable display substrate through one patterning process.

13. The stretchable display substrate according to claim 2, wherein the resistor is located at a junction between a connection bridge of the plurality of connection bridges and an island corresponding to the connection bridge.
